(19) United States
(12) Patent Application Publication
(10) Pub. No.: US 2003/0100177 A1
(43) Pub. Date: May 29, 2003

(54) Method of manufacturing semiconductor device

(76) Inventors: Hiroki Takewaka, Tokyo (JP); Noriaki Fujiki, Tokyo (JP); Junko Izumitani, Tokyo (JP)

Correspondence Address: Platon N. Mandros, BURNS, DOANE, SWECKER & MATHIS, L.L.P., P.O. Box 1404, Alexandria, VA, 22313-1404, US

(21) Appl. No.: 10/207,157

(22) Filed: Jul. 30, 2002

(30) Foreign Application Priority Data
Nov. 26, 2001 (JP) 2001-359808

(51) Int. Cl. H01L 21/4763; H01L 21/302

(52) U.S. Cl. 438/633; 438/692; 438/626

(57) ABSTRACT

Before polishing an insulating interlayer film by a CMP process, conductor plugs as erosion-inducing portions are formed on a convex surface of the film. Erosion occurs in the convex surface upon the CMP process, and the residual-free flat surface of insulating interlayer film can be obtained.

### BACKGROUND OF THE INVENTION

1. Field of the Invention

The present invention relates to a method of manufacturing a semiconductor device comprising a CMP process on an insulating interlayer film with concave and convex surfaces.

2. Background Art

With a view of micro-fabricating a semiconductor device (semiconductor integrated circuit device) and bringing it into high integration, a semiconductor device has recently been utilized extensively wherein a substrate or wring layer provided in a lower layer, and a wiring layer provided in an upper layer are connected to each other through conductor plugs formed within an insulating interlayer film by a CVD method.

A conventional semiconductor device will be described in brief with reference to FIGS. 7 and 8. FIG. 7 is a schematic cross-sectional view showing the conventional semiconductor device, and FIG. 8 is a schematic top view of the semiconductor device shown in FIG. 7, respectively.

In FIGS. 7 and 8, reference numeral 1 indicates a substrate such as a silicon substrate, reference numerals 3 indicate MOS gate insulting films formed on the substrate 1, reference numerals 4 indicate MOS gate electrodes formed on the gate insulating films 3, reference numerals 7 indicate lower wirings connected to the substrate 1, reference numeral 8 indicates an insulating interlayer film such as an oxide film formed between an upper layer and a lower layer, reference numerals 9 indicate upper wirings formed in the upper layer, reference numerals 10 indicate conductor plugs for electrically connecting the lower wirings 7 to the upper wirings 9, reference numerals 11 indicate barrier metal layers used as parts of the conductor plugs 10, which are formed around the conductor plugs 10, S indicates a concave surface on the insulating interlayer film 8, and M indicates a convex surface on the insulating interlayer film 8, respectively.

Here, the lower layer is formed of elements comprising the lower wirings 7, the gate oxide film 3 and the gate electrodes 4. A step between the concave surface S and the convex surface M takes place on the insulating interlayer film 8 in association with the looseness or non-denseness and denseness of both the lower wirings 7 and the elements for the lower layer. Described in detail, the convex surface M corresponds to a dense area in which the lower wirings 7 and the elements are relatively densely arranged, whereas the concave surface S corresponds to a non-dense area in which the lower wirings 7 and the elements are arranged in a relatively dispersed form.

The semiconductor device constructed as described above is manufactured via the following process steps.

A lower layer comprising lower wirings 7 is first formed on a substrate 1. Thereafter, an insulating interlayer film 8 such as an oxide film is formed on the lower layer by a CVD method. Next, a plurality of holes are defined in the insulating interlayer film 8 by photolithography. Further, barrier metal layers 11 are formed on the insulating interlayer film 8 with the plural holes defined therein. While the plurality of holes defined in the insulating interlayer film 8 are respectively reduced in diameter by the thicknesses of the barrier metal layers 11 at this time, the shapes of the open holes are held as they are.

Next, the insulating interlayer film 8 with the plurality of holes defined therein is filled with a conductor such as tungsten by the CVD method. At this time, the conductor fills in the plurality of holes and is deposited on the insulating interlayer film 8.

Thereafter, the conductor deposited on the insulating interlayer film 8 is polished by a CMP process (metal CMP process) until the surface of the insulating interlayer film 8 is exposed, thereby forming conductor plugs 10 corresponding to the number of the plural holes.

Afterwards, an upper layer is formed on the insulating interlayer film 8. Consequently, the lower wirings 7 and upper wirings 9 are electrically connected to one another by the conductor plugs 10 respectively.

The conventional semiconductor device has involved a case in which concave and convex surfaces are widely or locally formed on an insulating interlayer film before a CMP process. The concavity and convexity or irregularity on the insulating interlayer film are developed in the layer below the insulating interlayer film according to the degree of denseness of lower wirings and elements as previously described. Namely, the position of the surface of the insulating interlayer film corresponding to a dense area in which the lower wirings or the like are densified, becomes higher than the position of the insulating interlayer film corresponding to a non-dense area in which they are undensified.

It was difficult to eliminate a step on the insulating interlayer film, which is produced due to the non-denseness and denseness of the lower wirings and elements provided in such a lower layer, even if the CMP process is executed after the formation of the insulating interlayer film.

FIG. 9 is a schematic cross-sectional view showing a state of a post-CMP process semiconductor device. As shown in the same drawing, a residual 18 of a conductor is developed in a step portion at a boundary between a concave surface S and a convex surface M.

As described previously, the conductor is substantially uniformly deposited on the insulating interlayer film 8 by a conductor charging process step and polished according to the CMP process. Since, however, a scouring or polishing pad of a CMP processing device is ununiformly brought into contact with the step portion between the concave and convex surfaces, this CMP process will encounter difficulties in achieving the polishing of the conductor deposited thereon. There was a case in which the residual 18 of the conductor was developed in the step portion between the concave and convex surfaces in this way, and the residual was brought into contact with the upper wirings or the like, thereby causing a short in a circuit.

Further, when it is hard to remove the concave and convex surfaces on the insulating interlayer film after the CMP process, restrictions are imposed on the process of forming a subsequently-laminated upper layer. Namely, when the upper layer is formed on the insulating interlayer film having a step, it is necessary to set process conditions for photolithography, etching processing and the like for achieving reliable connections between conductor plugs and their corresponding upper wirings.

### SUMMARY OF THE INVENTION

The present invention has been made to solve the above problems. The present invention aims to provide a semiconductor device capable of, even if concave and convex surfaces are formed on an insulating interlayer film before a CMP process, reliably and simply flattening the concave and convex surfaces by its subsequent CMP process and providing high reliability and high production efficiency, and a manufacturing method thereof.

The present invention proposes a method of manufacturing a semiconductor device comprising a CMP process on an insulating interlayer film with concave and convex surfaces. The method comprises a step of forming, before the CMP process, erosion-inducing portions that induce to generate erosion in the CMP process, in an area corresponding to the convex surface on the insulating interlayer film.

Other and further objects, features and advantages of the invention will appear more fully from the following description.

### BRIEF DESCRIPTION OF THE DRAWINGS

The present invention will be more apparent from the following detailed description, when taken in conjunction with the accompanying drawings, in which;

FIG. 1 is a schematic cross-sectional view showing a semiconductor device according to the first embodiment of the present invention;

FIG. 2 is a schematic top view of the semiconductor device shown in FIG. 1;

FIG. 3 is a schematic cross-sectional view showing a semiconductor device according to the second embodiment of the present invention;

FIG. 4 is a schematic cross-sectional view showing a semiconductor device according to the third embodiment of the present invention;

FIG. 5 is a schematic cross-sectional view showing a semiconductor device according to the fourth embodiment of the present invention;

FIG. 6 is a schematic top view of the semiconductor device illustrated in FIG. 5;

FIG. 7 is a schematic cross-sectional view showing the conventional semiconductor device;

FIG. 8 is a schematic top view of the semiconductor device shown in FIG. 7;

FIG. 9 is a schematic cross-sectional view showing a state of a post-CMP process semiconductor device;

FIG. 10 is a schematic cross-sectional view showing a state of a semiconductor device before CMP process;

FIG. 11 is a schematic cross-sectional view showing a erosion state of a post-CMP process semiconductor device shown in FIG. 10.

### DETAILED DESCRIPTION OF THE PREFERRED EMBODIMENTS

The inventors of the present application have carried out further studies to solve the above problems, thus leading to findings of the following items.

Namely, a ratio of a surface area of a conductor charged into each hole (connecting hole or groove) to a surface area of an insulating interlayer film (hereinafter called “area-occupied ratio”) will be described. An area-occupied ratio at a convex surface on the insulating interlayer film is set higher than an area-occupied ratio at a concave surface, thereby making it possible to flatten the surface of the insulating interlayer film subsequent to a CMP process.

This is one which makes use of the property of erosion (insulating film chip-off) at the CMP process.

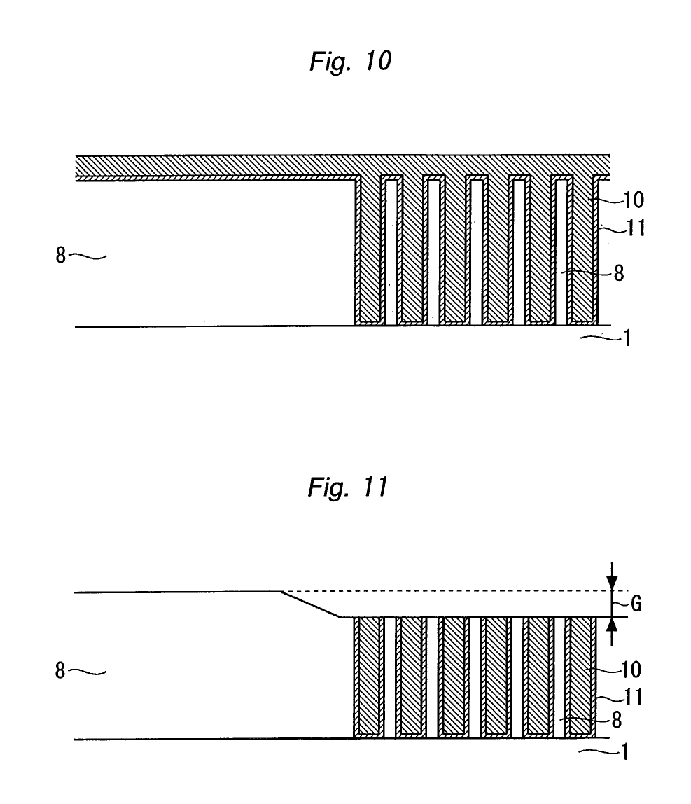

The erosion will be described in brief with reference to FIGS. 10 and 11. As shown in FIG. 10, a plurality of holes defined in an insulating interlayer film 8 are filled with a conductor 10 before a CMP process, and the insulating interlayer film 8 is covered with the conductor 10 thereover. Afterwards, the conductor 10 on the insulating interlayer film 8 is polished by the CMP process. At this time, a phenomenon, so-called erosion in which the insulating interlayer film 8 is chipped off considerably as compared with other area, is developed in an area high in area-occupied rate, of the conductor 10.

The present invention aims to cancel out a step developed in a pre-CMP insulating interlayer film by using a decrease G in film thickness due to the erosion at this time.

Embodiments of the present invention will hereinafter be described in detail with reference to the accompanying drawings. Incidentally, the same portions or corresponding portions in the drawings are identified by the same reference numerals, and the description of certain common portions will be suitably simplified or omitted.

First Embodiment

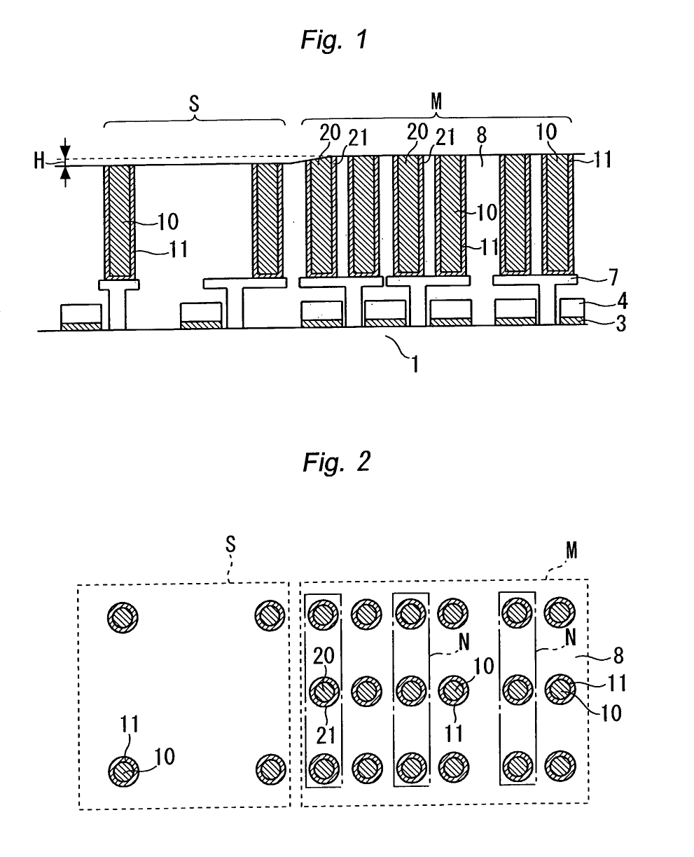

A first embodiment of the present invention will be described in detail with reference to FIGS. 1 and 2. FIG. 1 is a schematic cross-sectional view showing a semiconductor device according to the first embodiment of the present invention. FIG. 2 is a schematic top view of the semiconductor device shown in FIG. 1.

In FIGS. 1 and 2, reference numeral 1 indicates a substrate such as a silicon substrate, reference numerals 3 indicate MOS gate insulating films formed on the substrate 1, reference numerals 4 indicate MOS gate electrodes formed on the gate insulating films 3, reference numerals 7 indicate lower wirings connected to the substrate 1, reference numeral 8 indicates an insulating interlayer film such as an oxide film formed between an upper layer and a lower layer, reference numerals 10 indicate conductor plugs for electrically connecting the lower wirings 7 to upper wirings, reference numerals 11 indicate barrier metal layers used as parts of the conductor plugs 10 formed around the conductor plugs 10, reference numerals 20 indicate conductor plugs which electrically connect the lower wirings 7 to the upper wirings and are provided so as to induce erosion, reference numerals 21 indicate barrier metal layers formed around the conductor plugs 20, S indicates a concave surface on the insulating interlayer film 8, M indicates a convex surface on the insulating interlayer film 8, N indicates a conductor plug group disposed to induce erosion, and H indicates a step formed between the concave surface S and the convex surface M, respectively.

Here, the lower layer is formed of elements comprising the lower wirings 7, the gate insulating films 3 and the gate electrodes 4. The step H between the concave surface S and the convex surface M takes place on the insulating interlayer film 8 in association with the looseness or non-denseness and denseness of both the lower wirings 7 and the elements for the lower layer.

Referring to FIG. 2, the conductor plugs 10 and 20 formed in an area for the convex surface M are formed densely as compared with the conductor plugs 10 formed in an area for the concave surface S. Described in details, the conductor plug group N for the inducing the erosion is added to the number of the conventional conductor plugs 10 to enhance an area-occupied proportion or ratio of each conductor in the convex-surface M area. The conductor plugs 10 and 20 formed in the convex surface M on the insulating interlayer film 8 function as erosion-inducing portions for generating erosion upon a CMP process step to be described later.

Incidentally, the step H of the insulating interlayer film 8 prior to a CMP process can be estimated in some measure before the formation of the insulating interlayer film 8 according to the looseness and denseness of the lower wirings 7 and elements laid out in the lower layer. Namely, the conductor plugs 10 and 20 disposed in the insulating interlayer film 8 can be laid out in association with the non-denseness and denseness of the lower wirings 7 and each element laid out in the lower layer. Described in detail, the conductor plugs 10 and 20 are densely laid out at positions corresponding to dense areas in the lower layer, whereas the conductor plugs 10 are non-densely laid out at positions corresponding to non-dense areas.

The semiconductor device constructed as described above is manufactured via the following process steps.

A lower layer, which comprises lower wirings 7 or the like, is formed on a substrate 1. Thereafter, an insulating interlayer film 8 such as an oxide film is formed on the lower layer by a CVD method. Next, a plurality of holes are defined in the insulating interlayer film 8 by photolithography. Incidentally, the plurality of holes defined in the insulating interlayer film 8 are provided in association with the non-denseness and denseness of the conductor plugs 10 and 20.

Further, barrier metals layers 11 and 21 are formed on the insulating interlayer film 8 with the plurality of holes defined therein. While the plurality of holes defined in the insulating interlayer film 8 are respectively reduced in diameter by the thicknesses of the barrier metal layers 11 and 21 at this time, the shapes of the open holes are held as they are.

Next, the insulating interlayer film 8 with the plurality of holes defined therein is filled with a conductor such as tungsten by the CVD method. At this time, the conductor fills in the plurality of holes and is deposited on the insulating interlayer film 8.

Thereafter, the conductor deposited on the insulating interlayer film 8 is polished by the CMP process until the surface of the insulating interlayer film 8 is exposed, thereby forming conductor plugs 10 and 20 corresponding to the number of the plural holes.

Since, at this time, the plurality of conductor plugs 10 and 20 are provided on a convex surface M of the insulating interlayer film 8 as erosion-inducing portions, erosion occurs in the convex surface M upon the CMP process. Thus, a step H of the insulating interlayer film 8 is cancelled out and hence the residual-free flat surface of insulating interlayer film 8 can be obtained.

Afterwards, an upper layer is formed on the insulating interlayer film 8. Consequently, the lower wirings 7 and the upper wirings are electrically connected to one another by the conductor plugs 10.

In the semiconductor device configured as in the first embodiment, as described above, even if the concave and convex surfaces take place on the insulating interlayer film before the CMP process, the surface of the insulating interlayer film 8 provided with the conductor plugs 10 and 20 can be finished flat by a comparatively simple method based on the CMP process alone without adding a complex process step.

Thus, the residual of the conductor at the CMP process is reduced, and a process margin taken upon the formation of the upper layer on the insulating interlayer film 8 can be ensured.

Incidentally, the erosion-inducing portions were laid out in a design stage according to the looseness and denseness of the lower wirings 7 and elements laid out in the lower layer in the present embodiment. On the other hand, a design change for detecting the concave and convex surfaces of the insulating interlayer film 8 prior to the CMP process and ex-post adding a conductor plug group N is effected on the already-manufactured semiconductor device, and the result of its design change can also be reflected on a subsequently-manufactured semiconductor device. Even in this case, an effect similar to the first embodiment can be brought about.

In the first embodiment, the MOSs each made up of the gate insulating film 3 and the gate electrode 4 have been used as the elements disposed in the layer below the insulating interlayer film 8. However, the elements disposed in the lower layer are not limited to them, and a resistor, a capacitor and the like may be disposed therein.

Second Embodiment

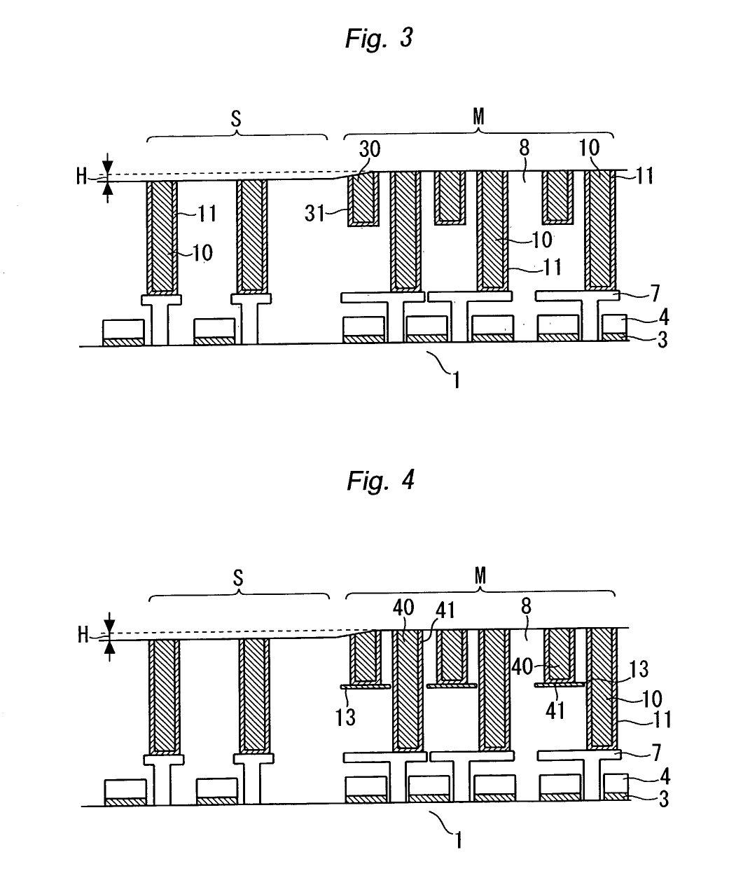

A second embodiment of the present invention will be described in detail with reference to FIG. 3. FIG. 3 is a schematic cross-sectional view showing a semiconductor device according to the second embodiment of the present invention.

The semiconductor device according to the second embodiment is different from the first embodiment in that dummy conductor plugs 30 are used as erosion-inducing portions formed in a convex surface of an insulating interlayer film.

In FIG. 3, reference numerals 10 indicate conductor plugs for electrically connecting lower wirings 7 to upper wirings, reference numerals 11 indicate barrier metal layers for the conductor plugs 10, reference numerals 30 indicate dummy conductor plugs placed for inducing erosion, and reference numerals 31 indicate barrier metal layers for the dummy conductor plugs 30, respectively.

Here, the dummy conductor plugs 30 comprise tungsten and are not connected to the lower wirings 7 and upper wirings. They do not function as connecting conductor plugs. Accordingly, each of lower ends of the dummy conductor plugs 30 is provided in a central portion of the insulating interlayer film 8 without contacting each of the lower wirings 7.

Incidentally, the dummy conductor plugs 30 are disposed so as to enhance area-occupied ratios of conductors in the convex surface M of the insulating interlayer film 8 for the purpose of generating erosion upon a CMP process step in a manner similar to the first embodiment. Namely, the normal conductor plugs 10 disposed in the convex surface M and the dummy conductor plugs 30 form the erosion-inducing portions in the second embodiment.

Incidentally, the dummy conductor plugs 30 can be laid out according to loose and dense conditions of the lower layer in a design stage in a manner similar to the first embodiment. A design change for ex-post adding the dummy conductor plugs 30 is made and the result of design change may also be reflected on a subsequently-manufactured semiconductor device.

The semiconductor device constructed as described above is manufactured via the following process steps.

A lower layer, which comprises lower wirings 7 or the like, is formed on a substrate 1. Thereafter, an insulating interlayer film 8 such as an oxide film is formed on the lower layer by a CVD method.

Next, a plurality of holes are defined in the insulating interlayer film 8 twice in parts by photolithography. Described in detail, holes for forming normal conductor plugs 10 and holes for forming dummy conductor plugs 30 are defined according to other etching process steps different in processing time from each other since they are different in open depth from one another.

Thereafter, barrier metals layers 11 and 31 are formed on the insulating interlayer film 8 with the plurality of holes defined therein. Next, a conductor is charged onto the insulating interlayer film 8 with the plurality of holes defined therein by the CVD method.

Thereafter, the conductor deposited on the insulating interlayer film 8 is polished by the CMP process until the surface of the insulating interlayer film 8 is exposed, thereby forming conductor plugs 10 and dummy conductor plugs 30 corresponding to the number of the plural holes.

Since, at this time, erosion-inducing portions are formed in a convex surface M of the insulating interlayer film 8, erosion occurs in the convex surface M upon the CMP process. Thus, a step H of the insulating interlayer film 8 is cancelled out and hence the residual-free flat surface of insulating interlayer film 8 can be obtained.

Afterwards, an upper layer is formed on the insulating interlayer film 8. Consequently, the lower wirings 7 and the upper wirings are electrically connected to one another by the conductor plugs 10.

Even in the semiconductor device configured as mentioned above as described in the second embodiment, even if the concave and convex surfaces are formed on the insulating interlayer film before the CMP process, the surface of the insulating interlayer film 8 provided with the conductor plugs 10 and the dummy conductor plugs 30 can be finished flat by a comparatively simple method based on the CMP process alone without adding a complex process step in a manner similar to the first embodiment.

Third Embodiment

A third embodiment of the present invention will be described in detail with reference to FIG. 4. FIG. 4 is a schematic cross-sectional view showing a semiconductor device according to the third embodiment of the present invention.

The semiconductor device according to the third embodiment is different from the second embodiment in that there are provided stopper layers 13 brought into contact with dummy conductor plugs.

In FIG. 4, reference numerals 10 indicate conductor plugs for respectively electrically connecting lower wirings 7 to upper wirings, reference numerals 11 indicate barrier metal layers for the conductor plugs 10, reference numerals 13 indicate stopper layers respectively brought into contact with lower ends of the dummy conductor plugs, reference numerals 40 indicate the dummy conductor plugs placed to induce erosion, and reference numerals 41 indicate barrier metal layers for the dummy conductor plugs 40, respectively.

Here, each of the stopper layers 13 is a material having etching resistance to etching specifications upon defining holes in an insulating interlayer film 8.

The semiconductor device constructed as described above is manufactured via the following process steps.

A lower layer made up of lower wirings 7 or the like is first formed on a substrate 1 in a manner similar to the second embodiment. Thereafter, an insulating interlayer film 8 such as an oxide film is formed on the lower layer by a CVD method. At this time, stopper layers 13 are formed in association with positions where the dummy conductor plugs 40 are formed.

Next, a plurality of holes are simultaneously formed in the insulating interlayer film 8 by photolithography. Described in details, holes for forming the normal conductor plugs 10 and holes for forming the dummy conductor plugs 40 are simultaneously defined in the same etching process.

At this time, the holes for the dummy conductor plugs 40 are different from those for the conductor plugs 10 and do not reach the lower layer because etching stops at their corresponding positions by the stopper layers 13.

Thereafter, barrier metal layers 11 and 41 are formed on the insulating interlayer film 8 with the plurality of holes defined therein. Next, the insulating interlayer film 8 with the plural holes defined therein is charged with a conductor by the CVD method.

Afterwards, the conductor deposited on the insulating interlayer film 8 is polished by a CMP process until the surface of the insulating interlayer film 8 is exposed, thereby forming conductor plugs 10 and dummy conductor plugs 40 corresponding to the number of the plural holes.

Even in the semiconductor device configured as mentioned above as described in the third embodiment, even if the concave and convex surfaces are formed on the insulating interlayer film before the CMP process, the surface of the insulating interlayer film 8 can be finished flat by a comparatively simple method based on the CMP process alone without adding a complex process step in a manner similar to the respective embodiments.

Since the third embodiment is provided with the stopper layers 13 disposed so as to contact the lower ends of the dummy conductor plugs 40 in addition to the above, an etching process step for defining the holes may be performed only once.

Fourth Embodiment

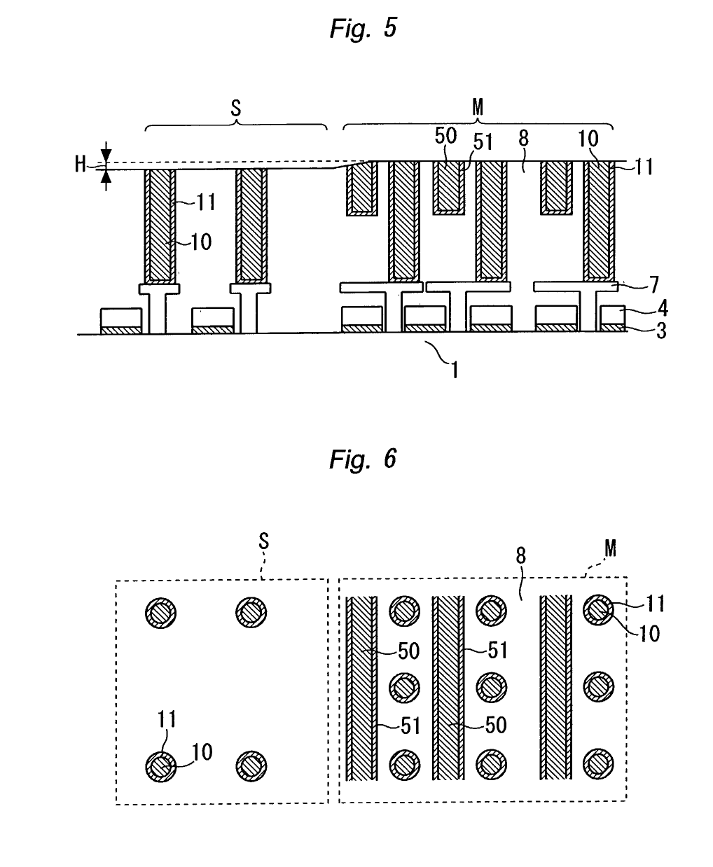

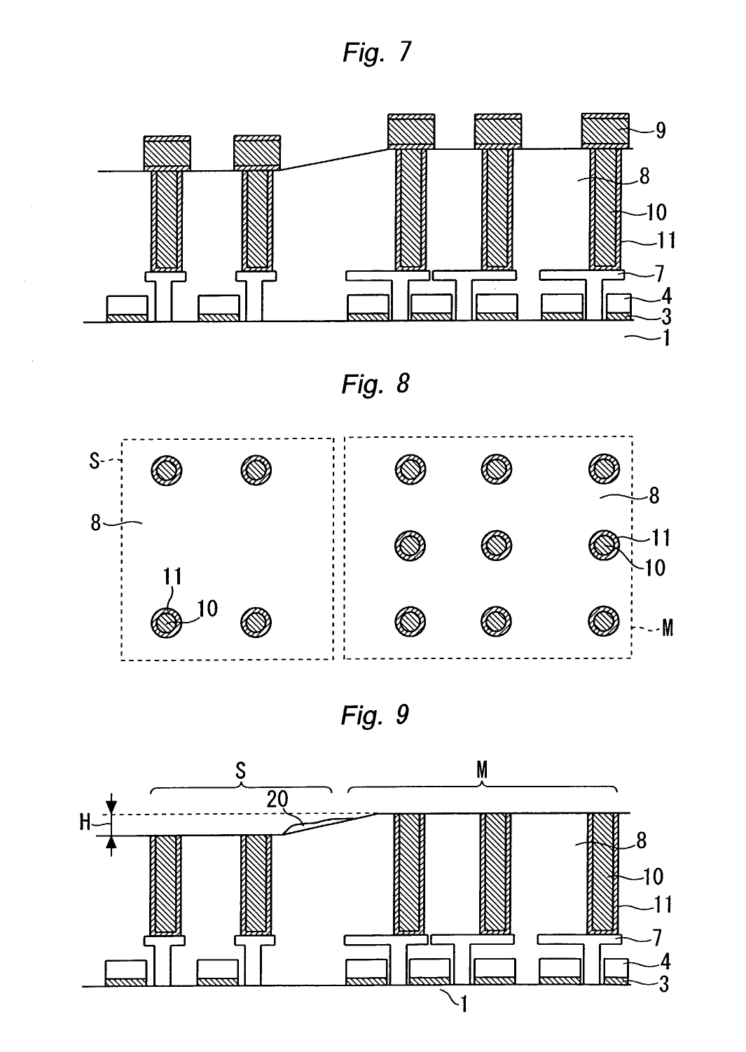

A fourth embodiment of the present invention will be described in detail with reference to FIGS. 5 and 6. FIG. 5 is a schematic cross-sectional view showing a semiconductor device according to the fourth embodiment of the present invention. FIG. 6 is a schematic top view of the semiconductor device illustrated in FIG. 5.

The semiconductor device according to the present embodiment is different from that according to the second embodiment in that buried wirings are used as an alternative to the dummy conductor plugs as erosion-inducing portions formed in a convex surface of an insulating interlayer film.

In FIGS. 5 and 6, reference numerals 10 indicate conductor plugs for respectively electrically connecting lower wirings 7 to upper wirings, reference numerals 11 indicate barrier metal layers for the conductor plugs 10, reference numerals 50 indicate buried wirings provided to induce erosion, and reference numerals 51 indicate barrier metal layers for the buried wirings 50, respectively.

Referring now to FIG. 5, the buried wirings 50 such as tungsten are disconnected from the lower wirings 7 and the upper wirings and do not function as so-called wirings. Accordingly, lower ends of the buried wirings 50 are provided at the central portion of the insulating interlayer film 8 without contacting the lower wirings 7 in a manner similar to the dummy conductor plugs 30 employed in the second embodiment.

Incidentally, the buried wirings 50 are disposed so as to enhance area-occupied ratios of conductors in the convex surface M of the insulating interlayer film 8 for the purpose of generating erosion upon a CMP process step as shown in FIG. 6 in a manner similar to the respective embodiments. Namely, the normal conductor plugs 10 disposed in the convex surface M and the buried wirings 50 form erosion-inducing portions in the fourth embodiment.

The semiconductor device constructed as described above is manufactured via the following process steps.

A lower layer, which comprises lower wirings 7, is first formed on a substrate 1 in a manner similar to the second embodiment. Afterwards, an insulating interlayer film 8 such as an oxide film is formed on the lower layer by a CVD method.

A plurality of holes corresponding to conductor plugs 10 are defined in the insulating interlayer film 8 by photolithography. Further, a plurality of grooves corresponding to buried wirings 50 are defined in the insulating interlayer film 8 by a damascene method.

Thereafter, barrier metal layers 11 and 51 are formed on the insulating interlayer film 8 with the holes and grooves defined therein. Next, a conductor is charged onto the insulating interlayer film 8 with the plural holes defined therein by the CVD method.

Afterwards, the conductor deposited on the insulating interlayer film 8 is polished by the CMP process until the surface of the insulating interlayer film 8 is exposed, thereby forming conductor plugs 10 corresponding to the number of the holes and buried wirings 50 corresponding to the number of the grooves.

Since, at this time, erosion-inducing portions are formed in a convex surface M of the insulating interlayer film 8, erosion occurs in the convex surface M upon the CMP process. Thus, a step H of the insulating interlayer film 8 is cancelled out and hence the residual-free flat surface of insulating interlayer film 8 can be obtained.

Afterwards, an upper layer is formed on the insulating interlayer film 8. Consequently, the lower wirings 7 and the upper wirings are electrically connected to one another by the conductor plugs 10.

Even in the semiconductor device configured as mentioned above as described in the fourth embodiment, above, even if the concave and convex surfaces take place on the insulating interlayer film before the CMP process, the surface of the insulating interlayer film 8 can be finished flat by a comparatively simple method based on the CMP process alone without adding a complex process step in a manner similar to the respective embodiments.

Incidentally, the present invention is not limited to the respective embodiments. It will be apparent that the respective embodiments can suitably be changed even other than those suggested in the respective embodiments within the scope of a technical idea of the present invention. Further, the number, positions, shapes and the like of the component members are not limited to the above embodiments. They may be set to the number, positions, shapes and the like suitable upon carrying out the present invention.

The main points are summarized in the following outline. According to one aspect of the present invention, a method of manufacturing a semiconductor device comprising a CMP process on an insulating interlayer film with concave and convex surfaces is proposed. The method comprises a step of forming, before the CMP process, erosion-inducing portions that induce to generate erosion in the CMP process, in an area corresponding to the convex surface on the insulating interlayer film.

Preferably, the erosion-inducing portions are a plurality of conductor plugs formed densely as compared with a plurality of conductor plugs formed in an area corresponding to a concave surface of concave and convex surfaces. The conductor plugs can be dummy plugs. Stopper layers brought into contact with lower ends of the dummy conductor plugs may be formed.

In another embodiment of the present invention, the erosion-inducing portions are buried wirings.

The convex surface corresponds to an area in which wirings and/or elements lying in a layer below the insulating interlayer film are made dense as compared with the concave surface of the concave and convex surfaces.

According to another aspect of the present invention, the present invention provides a semiconductor device as described below.

The semiconductor device comprises a lower layer including a non-dense area and a dense area in which wirings and/or elements are formed non-densely and densely respectively, and an insulating interlayer film formed on the lower layer. Further, erosion-inducing portions for generating erosion upon execution of a CMP process is formed, which are provided within the insulating interlayer film corresponding to the dense area.

Preferably, the erosion-inducing portions are a plurality of conductor plugs formed densely as compared with a plurality of conductor plugs formed within the insulating interlayer film corresponding to the non-dense area. The erosion-inducing portions can be a plurality of conductor plugs, dummy conductor plugs and/or buried wirings. Further, the semiconductor device may include stopper layers which contact lower ends of the dummy conductor plugs respectively.

In another embodiment the erosion-inducing portions are a plurality of conductor plugs and buried wirings.

Since the present invention is constructed as described above, there can be provided a semiconductor device capable of, even if concave and convex surfaces are formed on an insulating interlayer film before a CMP process, reliably and simply flattening the concave and convex surfaces by its subsequent CMP process and providing high reliability and high production efficiency, and a manufacturing method thereof.

The entire disclosure of a Japanese Patent Application No.2001-359808, filed on Nov. 26, 2001 including specification, claims drawings and summary, on which the Convention priority of the present application is based, are incorporated herein by reference in its entirety.

1. A method of manufacturing a semiconductor device comprising a CMP process on an insulating interlayer film with concave and convex surfaces, comprising:
a step of forming, before the CMP process, erosion-inducing portions that induce to generate erosion in the CMP process, in an area corresponding to the convex surface on the insulating interlayer film.

2. The method according to claim 1, wherein said erosion-inducing portions are a plurality of conductor plugs formed densely as compared with a plurality of conductor plugs formed in an area corresponding to a concave surface of concave and convex surfaces.

3. The method according to claim 2, wherein said erosion-inducing portions forming step is a step of forming dummy conductor plugs.

4. The method according to claim 3, wherein said dummy conductor plugs forming step includes a step of forming stopper layers brought into contact with lower ends of the dummy conductor plugs.

5. The method according to claims 1, wherein said erosion-inducing portions forming step is a step of forming buried wirings.

6. The method according to claims 1, wherein the convex surface corresponds to an area in which wirings and/or elements lying in a layer below the insulating interlayer film are made dense as compared with the concave surface of the concave and convex surfaces.
